(19) United States
(12) Patent Application Publication
(10) Pub. No.: US 2026/0212908 A1
(43) Pub. Date: Jul. 23, 2026

(54) BIT LINE MULTIPLEXER WITH ISOLATION IN THREE-DIMENSIONAL MEMORY CIRCUITS

(71) Applicant: Samsung Electronics Co., Ltd., Suwon-si (KR)

(72) Inventors: Moumita DUTTA, Fremont, CA (US); Adeniji ADETAYO, San Jose, CA (US); Sumaiya WAHID, San Jose, CA (US); Siwoo LEE, Saratoga, CA (US); Jaesoo AHN, San Jose, CA (US); Don Koun LEE, San Jose, CA (US); Sangmin HWANG, San Jose, CA (US); Anthony KANAGO, Fremont, CA (US); Nidhi AGRAWAL, Fremont, CA (US)

(21) Appl. No.: 19/402,967

(22) Filed: Nov. 26, 2025

Related U.S. Application Data
(60) Provisional application No. 63/748,388, filed on Jan. 22, 2025.

(51) Int. Cl. G11C 11/4074; G11C 5/06; H10B 12/00; H10D 1/68

(52) U.S. Cl. CPC G11C 11/4074; G11C 5/063; H10B 12/482; H10B 12/30; H10D 1/714

(57) ABSTRACT

A system and a method for a BL multiplexer circuit are disclosed. The BL multiplexer circuit includes a keeper and a selector. The keeper is configured to maintain a local bit line (LBL) at a voltage level during a pre-charge period. The selector is configured to connect the LBL to a global bit line (GBL) through a conductive path based on a selection signal during a charge-sharing period. The keeper and the selector are located between the GBL and an array area of a three-dimensional (3D) memory circuit.

### CROSS-REFERENCE TO RELATED APPLICATION

This application claims the priority benefit under 35 U.S.C. § 119(e) of U.S. Provisional Patent Application Ser. No. 63/748,388 filed on Jan. 22, 2025, the disclosure of which is incorporated by reference in its entirety as if fully set forth herein.

### TECHNICAL FIELD

The disclosure generally relates to memory devices. More particularly, the subject matter disclosed herein relates to bit line multiplexer with isolation in three-dimensional (3D) memory circuits.

### BACKGROUND

The present background section is intended to provide context only, and the disclosure of any concept in this section does not constitute an admission that said concept is prior art.

Three-dimensional (3D) memory configurations have been increasingly popular. 3D memory devices, such as vertically stacked dynamic random-access memory (VSDRAM) and vertical NAND (V-NAND) flash memory, include memory cells that are stacked vertically to increase storage density. One feature of 3D memory circuits is the arrangement of local bit lines (LBLs), global bit lines (GBLs), and sense amplifiers (SAs). As the memory density increases, the ratio between the number of LBLs and GBLs increases, causing reduction in sense voltage margin at the SAs.

Existing techniques for improving SA sense margin, however, face several challenges, especially for high density and high aspect ratio memory circuits. One technique is to limit the number of LBLs per SA. This technique requires a large number of SAs which leads to high area overhead. In addition, it also reduces the memory density.

The above information disclosed in this Background section is only for enhancement of understanding of the background of the disclosure and therefore it may contain information that does not constitute prior art.

### SUMMARY

To overcome these issues, systems and methods are described herein for a technique of multiplexing BLs with isolation. In some embodiments, a BL multiplexer circuit includes a keeper and a selector. The keeper is configured to maintain a local bit line (LBL) at a voltage level during a pre-charge period. The selector is configured to connect the LBL to a global bit line (GBL) through a conductive path based on a selection signal during a charge-sharing period. The keeper and the selector are located between the GBL and an array area of a three-dimensional (3D) memory circuit.

In some embodiments, a process of forming an isolation layer to protect a bit line multiplexing circuit (BLMC). The process includes first etching to create a first etch, filling spacer into the first etch, performing a second etching into a silicon-germanium layer, filling spacer to surround a BLMC, and forming an LBL, a GBL, a set of WLs, and a capacitor array. In some embodiments, the first etching is a deep trench isolation (DTI) etching and the second etching may be an isolation (ISO) etching that creates deep and long trenches.

### BRIEF DESCRIPTION OF THE DRAWINGS

In the following section, the aspects of the subject matter disclosed herein will be described with reference to exemplary embodiments illustrated in the figures, in which:

FIG. 1 is a block diagram illustrating a system that utilizes a 3D memory circuit according to an embodiment.

FIG. 2 is a diagram illustrating a 3D memory circuit that utilizes a BL multiplexing circuit according to an embodiment.

FIG. 3 is a diagram illustrating a BL multiplexing circuit according to an embodiment.

FIG. 4 is a diagram illustrating a structure with GBL and BL multiplexing circuits according to an embodiment.

FIG. 5 is a diagram illustrating a structure having a BL multiplexing circuit with an isolation structure using a first option according to an embodiment.

FIG. 6 is a diagram illustrating a structure having a BL multiplexing circuit with an isolation structure using a second option according to an embodiment.

FIG. 7A is a diagram illustrating a first part of a fabrication process for the first isolation option according to an embodiment.

FIG. 7B is a diagram illustrating a second part of a fabrication process for the first isolation option according to an embodiment.

FIG. 8A is a diagram illustrating a first part of a fabrication process for the second isolation option according to an embodiment.

FIG. 8B is a diagram illustrating a second part of a fabrication process for the second isolation option according to an embodiment.

FIG. 9A is a diagram illustrating a BL multiplexing circuit with a single gate according to an embodiment.

FIG. 9B is a diagram illustrating a BL multiplexing circuit with a two-finger configuration according to an embodiment.

FIG. 9C is a diagram illustrating a structure with recessed channel width configuration according to an embodiment.

FIG. 9D is a diagram illustrating a single gate BL multiplexing circuit with recessed channel width configuration according to an embodiment.

FIG. 10 is a diagram illustrating a process of forming an isolation layer to protect a BLMC according to an embodiment.

FIG. 11 is a flow chart illustrating a first part of the process of performing the second etching based on the first option according to an embodiment.

FIG. 12 is a flow chart illustrating a second part of the process of performing the second etching based on the first option according to an embodiment.

FIG. 13 is a flow chart illustrating a first part of the process of performing the second etching based on the second option according to an embodiment.

FIG. 14 is a flow chart illustrating a second part of the process of performing the second etching based on the second option according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements. In the following, figures depicting various components, structures, interconnections, configurations, and steps of fabrication, are mainly for illustrative purposes. They are not intended to describe these elements accurately. A cross-sectional representation may be used to refer to a 3D block in a 3D structure. In some cases, relevant parts in a figure are shown clearly while other parts are shown with less sharpness or clarity to avoid confusion and improve contrast and clarity. These parts may be referenced in earlier figures and therefore do not need to be described again. These parts may also have little relationship with the part(s) being described. In addition, the shading of the parts in the figures may not have a consistent design and may be changed to maintain clarity and contrast in the figures. For example, part A may have a light shading in Fig. X but may be heavily shaded in Fig. Y. Moreover, as mentioned above, components in a figure may not be drawn with proper scales.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Many applications, especially applications in Artificial Intelligence (AI) and signal processing, require a vast storage capacity and high-throughput computations. To satisfy these needs, highly dense memory circuits in 3D are developed. A typical 3D dynamic random-access memory (DRAM) device may stack multiple layers of memory cells vertically. Bit lines (BLs) and word lines (WLs) may be arranged vertically to access cells in different layers. BLs and WLs are conductive elements that are used to select memory cells which may be arranged in a row-and-column array.

In the following, systems and methods are described for a technique of multiplexing BLs using a BL multiplexer circuit. The BL multiplexer circuit includes a keeper and a selector. The keeper is configured to maintain a local bit line (LBL) at a voltage level during a pre-charge period. The selector is configured to connect the LBL to a global bit line (GBL) through a conductive path based on a selection signal during a charge-sharing period. The keeper and the selector are located between the GBL and an array area of a three-dimensional (3D) memory circuit.

In some embodiments, at least one of the keeper or the selector is isolated from the LBL and an adjacent cell array by a dielectric layer. The dielectric layer surrounds the keeper, the selector or both. In addition, at least one of the keeper or the selector is arranged in a multi-finger configuration. This configuration may include a transistor having a channel surface folded along a width direction. The folded channel surface increases the effective channel width of the transistor, which may increase the drain saturation current. The increased drain saturation current helps increase the drive current to accommodate large load.

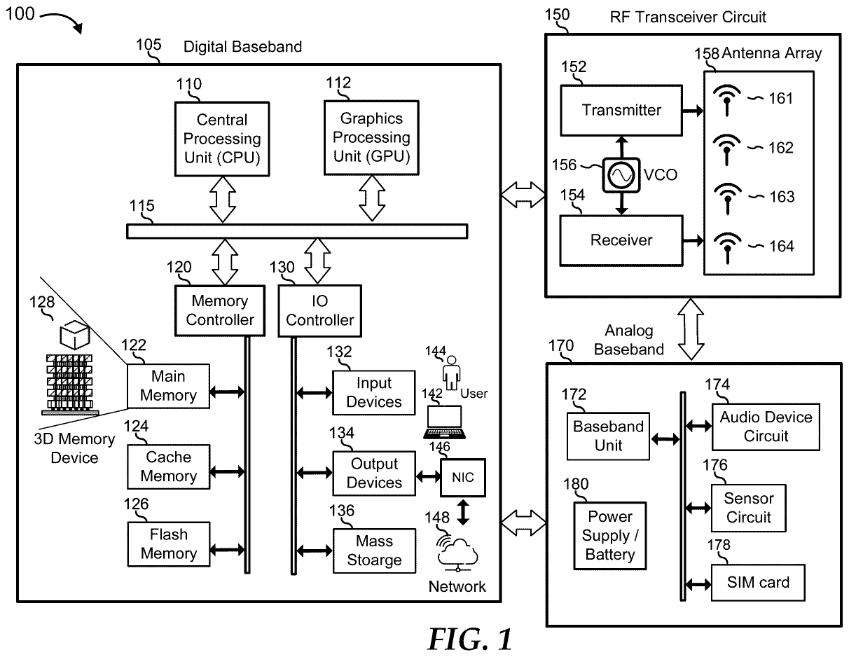

FIG. 1 is a block diagram illustrating a system that utilizes a 3D memory circuit according to an embodiment. The system 100 includes a digital baseband circuit 105, a radio frequency (RF) transceiver circuit 150, and an analog baseband circuit 170. The system 100 may represent a digital system or a mobile system. When the system 100 is used as a digital system without mobile circuitry, the RF transceiver circuit 160, and the analog baseband circuit 190 are not used. In addition, when the system 100 is used as a mobile device, many of the digital devices are scaled back and some devices may not be available.

The digital baseband circuit 105 includes a central processing unit (CPU) 110, a graphics processing unit (GPU) 112, a memory controller 120, and an IO controller 130. The system 100 may include more or less than the above components. In addition, a component may be integrated into another component. The integration may be partial and/or overlapped. For example, the memory controller 120 and the I/O controller 130 may be integrated into one single controller.

The CPU 110 is a programmable device that may execute a program or a collection of instructions to carry out a task. It may be a host that controls or manages other processors or devices. In particular, the CPU 110 may include applications programming interfaces (APIs), applications, or drivers that are executed by the CPU 110 to perform specified tasks. The CPU 110 may be a general-purpose processor, a digital signal processor, a microcontroller, or a specially designed processor. It may include a single core or multiple cores. Each core may have multi-way multi-threading. The CPU 110 may have simultaneous multithreading feature to further exploit the parallelism due to multiple threads across the multiple cores. In addition, the CPU 110 may have internal caches at multiple levels.

The GPU 112 is a specialized processor designed to perform computationally intensive tasks such as image analysis, graphics rendering, and neural computations. In addition, the GPU 112 may be designed with parallel processing capability, suitable for parallel computations in artificial intelligence (AI) applications including machine learning (ML), large language model (LLM), and neural networks (NN). The GPU 112 may be used to accelerate training and running AI models. It may include multiple computational accelerators or tensor cores which are optimized for basic AI computations such as matrix multiply-accumulate operations

The CPU 110 and the GPU 112 communicate with other devices in the system via a bus 115. The bus 115 may be any suitable bus connecting the CPU 110 and/or the GPU 112 to other devices. For example, the bus 115 may be a Direct Media Interface (DMI). The bus 115 may also include other custom buses such as bus for the interface to the analog section when the system 100 is used as a mobile device. Additional devices or bus interfaces may be available for interconnections and/or expansion. Some examples may include the Peripheral Component Interconnect Express (PCIe) bus, the Universal Serial Bus (USB), etc.

The memory controller 120 controls memory devices such as a main memory 122, a cache memory 124, and a flash memory 126. The main memory 122 includes random access memory (RAM) including static RAM (SRAM) and dynamic RAM (DRAM) and/or the read-only memory (ROM) and other types of memory. The DRAM may include Synchronous DRAM (SDRAM), Double Data Rate SDRAM (DDR SDRAM) with variations (e.g., DDR2, DDR3, DDR4, DDR5, and DDR6). The main memory 122 may store instructions or programs, loaded from a mass storage device, that, when executed by the CPU 110, cause the CPU 110 to perform operations for a specified task. It may also store data used in the operations. The ROM may be a solid-state drive (SSD) and include instructions, programs, constants, or data that are maintained whether it is powered or not. The instructions or programs may correspond to the functionalities described in the following. In one embodiment, the main memory 122 includes a 3D memory device or circuit 128 such as VSDRAM and V-NAND flash memory, or any other memory devices that have memory cells that are stacked vertically to increase storage density

The I/O controller 130 controls input devices 132, output devices 134, and mass storage 136. The input devices 132 may include a keyboard, a mouse, an image sensor or camera, a game console, and a microphone. Other input devices may also be available such as stylus, joystick, scanner, and light pen. The input devices may also have a user interface to interface to a computer or laptop 142 and/or a user 144. The output devices 134 may include a printer, a monitor or screen, a headset, and a multi-monitor set. When used as a computing device without mobile features, the monitor is a high-resolution display. For games and other multi-display mode, the multi-monitor set provides high-resolution with multiple monitors (e.g., three monitors). When used for mobile communication, the screen provides the primary interface for the user to navigate, access various applications and perform tasks. The screen may use organic light-emitting diode (OLED) (super retina) display with multi-touch or haptic touch feature. The mass storage 136 may include CD-ROM, hard disk, and solid-state drives (SSDs). The I/O controller 130 also has a network interface card (NIC) 145 which provides an interface to a network and wireless medium 148.

The RF transceiver circuit 150 includes a transmitter 152, an antenna array 158, a voltage-controlled oscillator (VCO) 156, and a receiver 154. The RF circuit 150 operates at a high GHz frequency band to accommodate modern cellular equipment such as the wireless fifth generation (5G).

The transmitter 152 transmits the digital baseband data to the antenna array 158. The transmitter 152 may include a digital-to-analog converter (DAC), an automatic gain controller (AGC), an intermediate frequency (IF) circuit, a mixer, an RF circuit, and a power amplifier (PA). Other components may include filters, amplifiers, multiplexers, coaxial cables, phase shifters, etc. The DAC converts digital data f₁ into an analog signal f₂. The AGC automatically adjusts the signal amplitude of f₂ to generate a signal f₃ to maintain a consistent strength level in a dynamic and changing environment. The IF circuit performs intermediate frequency processes such as filtering to generate a signal f₄. The mixer converts the frequency of the signal f₄ to another frequency. This is done by mixing the signal f₄ with a signal vₜ from the VCO 156. Mixing here refers to frequency modulation which translates the signal f₄ to a signal f₅ at a different frequency. For transmitter, the translated frequency is higher than the frequency of f₄. The conversion is called up-conversion. For 5G communication, the frequency range may include low-band (below 1 GHz), mid-band (1 GHz to 6 GHz), and high-band (24 GHz to 53 GHz or higher). The resulting signal f₅ then goes through various radio frequency processes performed by the RF circuit such as high-pass filtering to produce a signal f₆. The signal f₆ is strengthened and amplified by the PA to produce a signal f₇. The signal f₇ then goes to the antenna array 158 to be transmitted to an appropriate destination and medium (e.g., base station). The antenna array 158 uses beam forming to focus radio waves from f₇ in a desired direction. The antenna array 158 may be used for both transmitting and receiving. On receiving, the antenna array 158 receives an RF signal and sends it to the receiver 154. The number of antennas in the antenna array 158 depends on the desired coverage. The antenna array 158 may include antennas 161, 162, 163, and 164 configured to operate with 5G communication, Gigabit Long Term Evolution (LTE), Wi-Fi (e.g., 2.4 GHz, 5 GHz, and 6Ghz), and Bluetooth, respectively. The number of antennas may be more or less than the above.

The VCO 156 couples multiple in-phase oscillators together to provide low phase noise oscillation. It generates signals vₜ and vᵣ to the mixers at specified frequencies. It may include multiple oscillation core circuits (or VCO cores) to provide high-frequency periodic signals.

The receiver 154 processes the received signal r₇ in a manner reverse from the transmitter 152. It may include a low noise amplifier (LNA), an RF circuit, a mixer, an IF circuit, an AGC, and an analog-to-digital converter (ADC). The receiver 154 may include more or less than the above components. The LNA amplifies the weak signal r₇ while maintaining a good signal-to-noise ratio (SNR) to produce a signal r₆ for further processing. The signal r₆ is next processed by the RF circuit such as band-pass filtering to provide a signal r₅. Additional filtering may be performed in the next stages. The signal r₅ is then mixed with the signal vᵣ from the VCO 156 to down convert the signal r₅ to a signal r₄ at an appropriate low frequency. Like the mixer in the transmitter 152 but with a reverse operation, the mixer in the receiver performs frequency modulation to translate the high frequency signal r₅ to a low frequency signal r₄. The signal r₄ goes through IF processing such as additional filtering by the IF circuit to produce a signal r₃. The AGC amplifies and strengthens the signal and generates a signal r₂. The ADC converts the analog signal r₂ into digital data r₁ which will be processed by the CPU 110.

The analog baseband circuit 170 provides analog processing for various components. It handles processing of signals and data between the digital baseband circuit and the RF transceiver circuit 150. It may include analog and digital components to perform various tasks including modulation/demodulation, controlling the RF transceiver circuit 150, special circuitry for 3G, 4G/LTE, Bluetooth, and 5G communication. It may also interface with an audio device circuit 174, a sensor circuit 176, a Subscriber Identity Module (SIM) card 178, and other components. The audio device circuit 174 may include operational blocks to process audio signals and perform audio-related functions such as filtering, correlation, speech recognition. It may include digital circuits to perform Fast Fourier Transform (FFT) to perform signal processing in the frequency domain. The sensor circuit 176 may include a variety of sensors such as proximity, ambient light, motion (accelerometer and gyroscope, compass, barometer, fingerprint sensor for touch identification (ID), image sensors for face ID, light detection and ranging (LiDAR) scanner, etc. The SIM card 178 is a small, removable chip that stores the user's phone number and carrier information, allowing the device to connect to a cellular network.

The power supply and battery circuit 180 provides power and battery backup supply to the entire system. It may include a charger to charge the battery. The battery may be a rechargeable battery, of Lithium-Ion battery. Power management may be performed by application software and circuits to provide low power mode and performance management.

The system 100 is an example that illustrates the role of 3D memory devices in a laptop, desktop or mobile environment. In many cases, the environment of the applications adds additional requirements including low power consumption, reliable signal integrity, fault-tolerance, and reliable operations in extreme conditions including heat and tight space. Examples of other applications that would benefit from 3D memory devices or circuits include mobile communication (e.g., smart phones, base stations, user equipment), cameras, vehicles, entertainment (e.g., games, multimedia, music, movies), technical designs (e.g., animation, graphics), medical (e.g., visualization, medical imaging), robotics, drones, automatic test equipment, audio processing, speech synthesizer, video and image analysis, vision, automatic face recognition, artificial intelligence (AI) applications, and data centers.

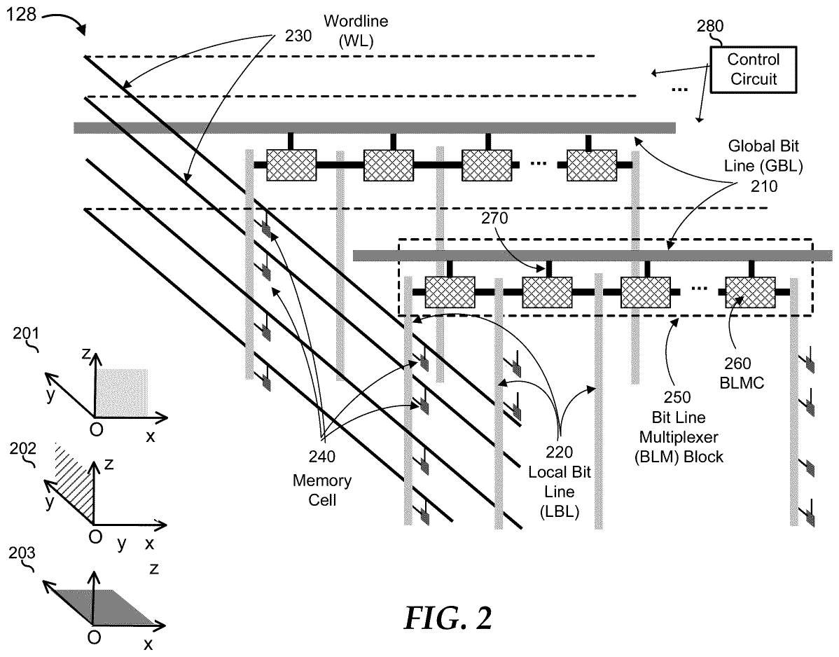

FIG. 2 is a diagram illustrating a 3D memory circuit 128 shown in FIG. 1 that utilizes a BL multiplexing circuit according to an embodiment. The 3D memory circuit 128 includes a 3D structure having planes defined according to a coordinate system of Ox, Oy, and Oz 201, 202, and 203. The planes 201, 202, and 203 refer to an xOz plane, an yOz, and an xOy plane, respectively. For clarity, only relevant components are shown. In addition, component indices are not used and components with different indices are shown without indices. The 3D memory circuit 128 includes GBLs 210, LBLs 220, WLs 230, memory cells 240, and a control circuit 280. The 3D memory circuit 128 includes vertical stacks of 2D planes of memory cells (e.g., the 201 xOy plane). The memory cells 240 are arranged in a 3D structure which may include any of the planes 201, 202, and 203. The memory cells 240 are addressed by the WLs 230 and the LBLs 220. The LBLs are grouped into groups and connected to GBL 210. In one embodiment, each GBL 210 is connected to a group of LBLs 220 via a bit line multiplexing (BLM) block 250. The BLM block 250 includes N individual BLM circuits (BLMCs) 260. Each BLMC 260 connects a LBL 220 to the corresponding GBL 210 via a conductive path 270.

The BLMC 260 selects a LBL 220 to be connected to the GBL 210 via the corresponding conductive path 270 by a selection signal generated by the control circuit 280 according to an access timing scheme. By allowing multiple LBLs to be selectively connected to a GBL 210 one at a time, the BLMC 260 increases the memory density while keeping the silicon area for the SAs low. In addition, each BLMC 260 has a recessed channel width that helps increase the channel surface width which in turn increases the drain saturation current (IDSAT). The high IDSAT provides a high drive capability for driving circuits in the SAs and others. In addition, a high IDSAT also provides fast switching times.

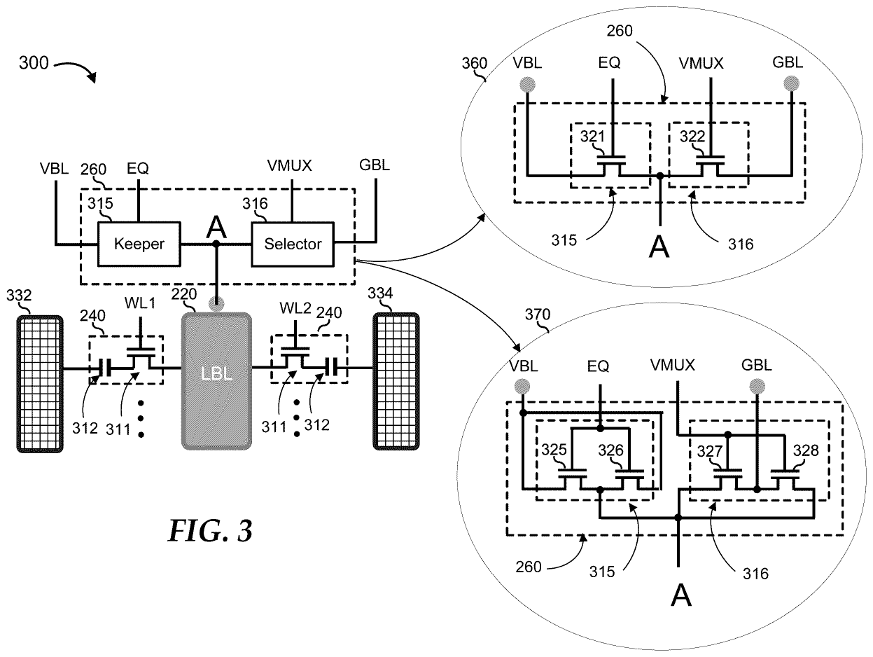

FIG. 3 is a diagram illustrating a circuit 300 that includes the BL multiplexing circuit (BLMC) 260 shown in FIG. 2 according to an embodiment.

The circuit 300 includes the BLMC 260, the LBL 220, cell array supports 332 and 334, memory cells 240, The circuit 300 may include more or less than the above components. The cell array supports 332 and 334 are polysilicon structures that house or support the cell array including the memory cells 240. Each memory cell 240 includes at least a transistor 311 and a capacitor 312. The transistor 311 acts as a switch to control the connection between the capacitor 312 and the LBL 220. The gate of the transistor 311 is connected to the corresponding WL 230. Two WLs are shown as an example: WL1 and WL2. The capacitor 312 may be implemented as two electrodes surrounding a dielectric layer. The capacitor 312 may be pre-charged to prepare for a memory access in a pre-charge period. During the pre-charge period, the LBL 220 may be charged to a voltage level that is close to a logic 0 or a logic 1 so that when a memory access is activated, the SA can sense the cell voltage quickly. In some embodiments, this voltage level is approximately equal to half the power supply voltage (e.g., V_{DD}/2). When a memory access (read or write) starts, the memory cell 240 operates in a charge-sharing period during which time the charge from the capacitor 312 is shared with the LBL 220, causing a slight voltage change according to whether the capacitor stores a logical 1 or 0. An SA associated with the LBL 220 and the corresponding memory cell 240 detects this small voltage difference and amplifies it to the correct logic 1 at the V_{DD} level or logic 0 at the zero volt level.

The BLMC 260 operates based on the above timing scheme. It includes a keeper 315 and a selector 316. The keeper 315 and the selector 316 are connected at a point A connection point to the LBL 220. The keeper 315 is connected to a voltage source VBL that provides the voltage for the pre-charge period. In some embodiments, this voltage level is equal to half of the power supply voltage, V_{DD}/2. The keeper 315 is a circuit that is configured to maintain the LBL 220 at the above pre-charge voltage level during a pre-charge period (e.g., V_{DD}/2). The keeper is controlled by an EQ signal. The selector 316 is connected to the associated GBL 210 through the conductive path 270 (shown in FIG. 2). The connection to the GBL is controlled by a selection signal VMUX. The selector 316 is a circuit that is configured to connect the LBL 220 to the GBL 210 based on the selection signal VMUX during a charge-sharing period. The EQ and VMUX signals are provided by the control circuit 280 (shown in FIG. 2).

There are at least two types of circuit that implements the BLMC 260: a single-finger circuit 360 and a multi-finger circuit 370. The single-finger circuit 360 is simple and occupies less area. The multi-finger circuit 370 occupies a larger area with an advantage of reduced gate resistance, lowered parasitic effects, and increased drive current. In a multi-finger circuit, the three terminals of a transistor are laid out in an alternating pattern that looks like human fingers. All the gate fingers are connected to form a single gate terminal. All the source and drain fingers are connected to form single source and drain terminals, respectively.

In the single-finger circuit 360, the keeper 315 includes a single transistor 321 and the selector 316 includes a single transistor 322. During the pre-charge period, the WLs are inactivated, or LOW, turning off all transistors in the memory cell 240. At the same time, the EQ signal is HIGH, turning on the transistor 321. The voltage level at the voltage source VBL is transferred to point A. The VMUX is HIGH, connecting point A to the GBL. The GBL is therefore the VBL voltage level, typically at V_{DD}/2. During the charge-sharing period, the EQ signal is LOW, turning off the transistor 321. The WL2 is HIGH, turning on the corresponding transistor 311 in the memory cell 240. The charge is transferred to the LBL 220 and to point A. The VMUX signal is HIGH, turning on the transistor 322. The LBL 220 is therefore connected to the GBL.

When the VMUX is low, the corresponding LBL 220 is disconnected from the GBL. Accordingly, by controlling the selection signal VMUX, the corresponding LBL 220 is connected to or disconnected from the GBL. When multiple LBLs are connected to a GBL, at most one LBL is allowed to be connected to the GBL. When one LBL is connected to the GBL, the rest of the LBLs in the group are disconnected.

In the multi-finger circuit 370, a similar operation takes place. For illustrative purposes, a two-finger configuration is shown. The operation is the same for any number of fingers. In the illustrative example of the two-finger configuration, the keeper 315 includes transistors 325 and 326 connected together. The gates, drain and source terminals are connected together. The gates are connected to the EQ signal. One of the drain and source terminals is connected to the VBL voltage source. The other terminals are connected to point A which is connected to the selector 316. The selector 316 includes two transistors 327 and 328 connected together. The gates, drain and source terminals are connected together. The gates are connected to the VMUX signal. One of the drain and source terminals is connected to the GBL. The other terminals are connected to point A which is connected to the keeper 315 and the LBL 220.

During the pre-charge period, the WLs are inactivated, or LOW, turning off all transistors in the memory cell 240. At the same time, the EQ signal is HIGH, turning on both the transistors 325 and 326. The voltage level at the voltage source VBL is transferred to point A. The VMUX is HIGH, connecting point A to the GBL. The GBL is therefore the VBL voltage level, typically at V_{DD}/2. During the charge-sharing period, the EQ signal is LOW, turning off both the transistors 325 and 326. The WL2 is HIGH, turning on the corresponding transistor 311 in the memory cell 240. The charge is transferred to the LBL 220 and to point A. The VMUX signal is HIGH, turning on both the transistors 327 and 328. The LBL 220 is therefore connected to the GBL. When the VMUX signal is LOW, the GBL is disconnected from the LBL 220.

In some embodiments, in the implementation of the BLMC 260, the keeper and the selector are located at a location between a capacitor or cell array area and the GBL. In some embodiments, this location is at a top silicon layer of the 3D memory circuit because this top silicon layer is typically not fully used.

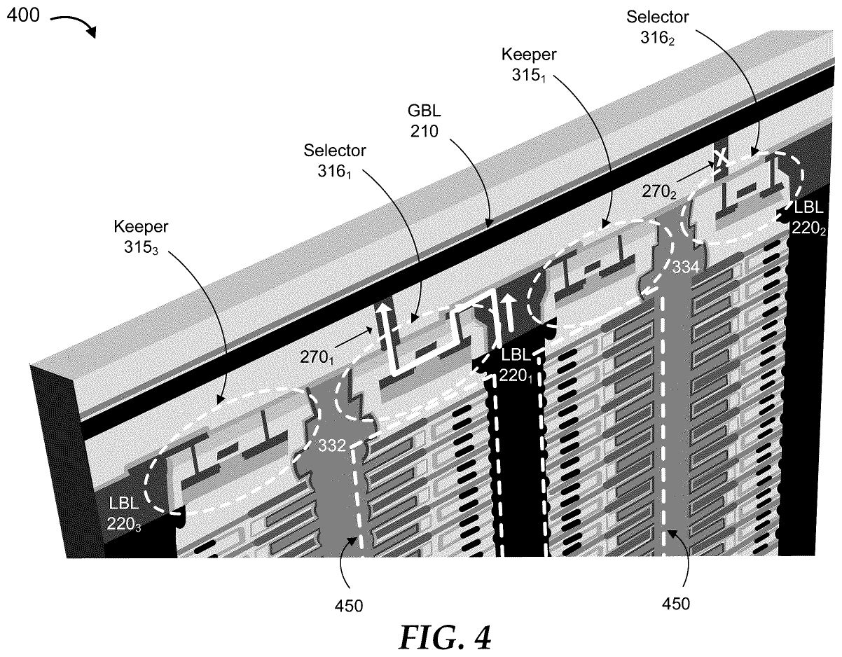

FIG. 4 is a diagram illustrating a structure 400 with GBL and BL multiplexing circuits according to an embodiment. The structure 400 is an illustrative 3D structure of the circuit 300 shown in FIG. 2. For ease of reference, an index (1, 2, 3) is used for the labels of the components. In addition, due to lack of space, not all components are shown. Furthermore, the actual locations of the keeper 315 and selector 316 may be swapped. The BLMC 260 uses the single-finger configuration.

The structure 400 includes a GBL 210, three LBL 220₁, 220₂, and 220₃, and a capacitor array 450. The LBL 220₁ operates with a keeper 315₁ and a selector 316₁. The LBL 420₂ operates with a keeper 315₂ (not shown due to lack of space) and a selector 316₂. The LBL 420₃ operates with a keeper 315₃ and a selector 316₃ (not shown due to lack of space). The capacitor array 450 may be associated with the LBL 220₁. The BLMC 260₁ includes the keeper 315₁ and the selector 316_{1.} The BLMC 260₂ includes the keeper 315₂ (not shown due to lack of space) and the selector 316₂. The BLMC 260₃ includes the keeper 315₃ and the selector 316₃ (not shown due to lack of space). The keeper 315ⱼ's and selector 316ⱼ's are located external to the cell or capacitor array 450.

As shown in FIG. 4, the BLMCs 260₁, 260₂, and 260₃ are implemented in the top layer of the 3D structure 400. The BLMC 260₁ is shown in the charge-sharing period. The corresponding WL is activated, the VMUX signal in the selector 316₁ is asserted HIGH, and the EQ signal in the keeper 315₁ is de-asserted LOW. The corresponding conductive path 270₁ between the LBL 220₁ and the GBL 210 is shown connected. At the same time, all other selectors are deselected and the corresponding LBL 220s are disconnected from the GBL 210. For example, the conductive path 270₂ is shown disconnected.

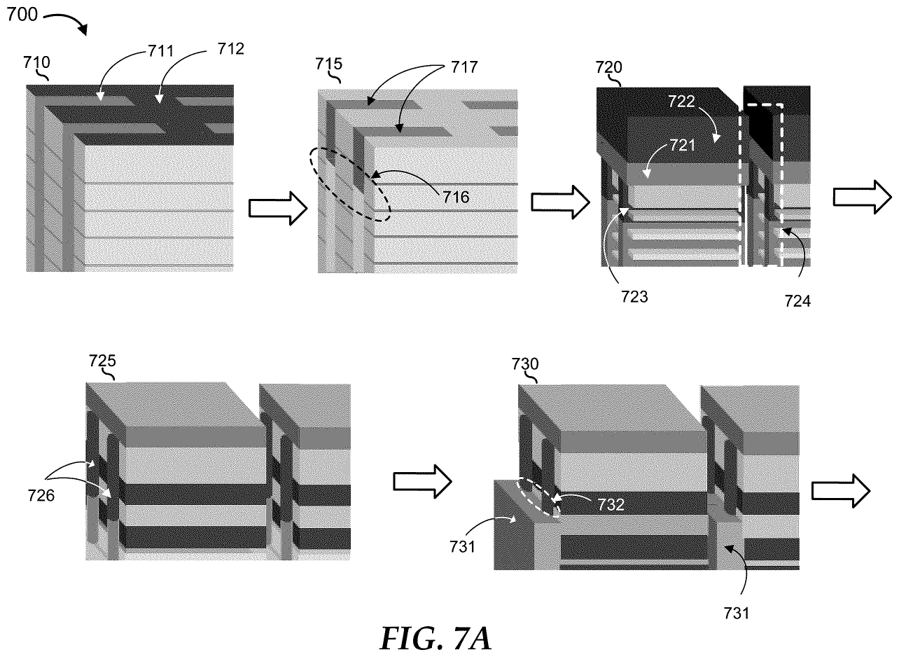

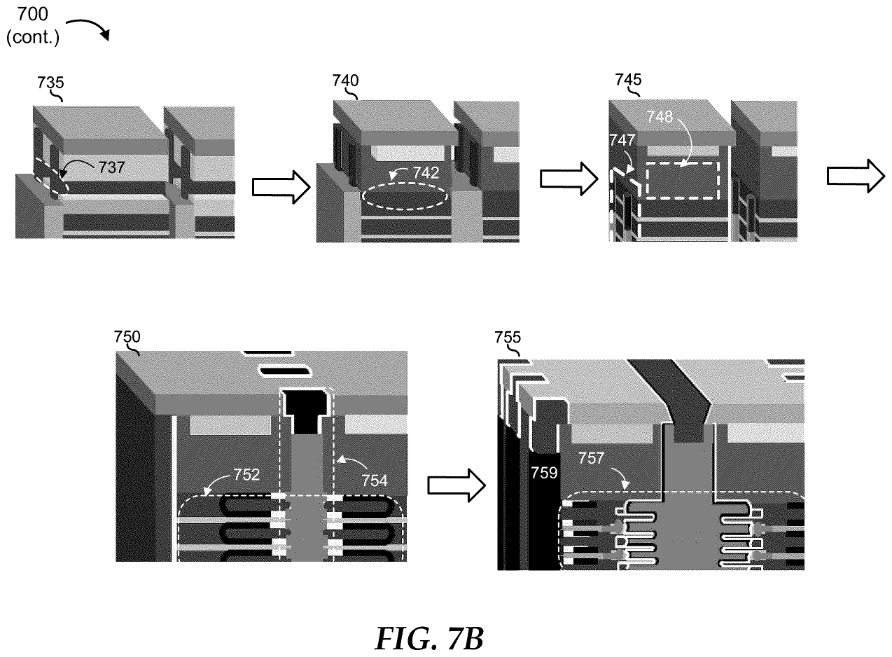

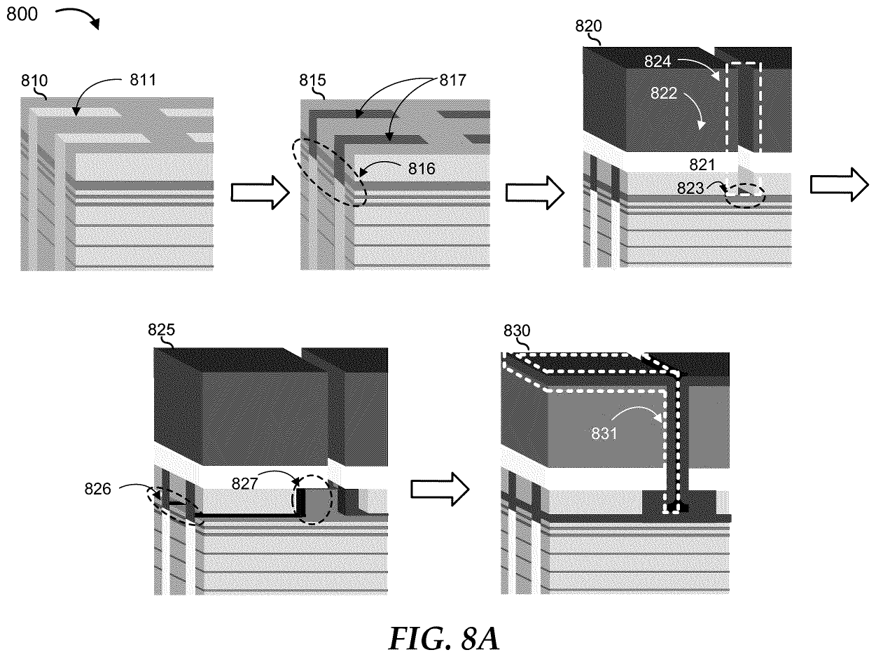

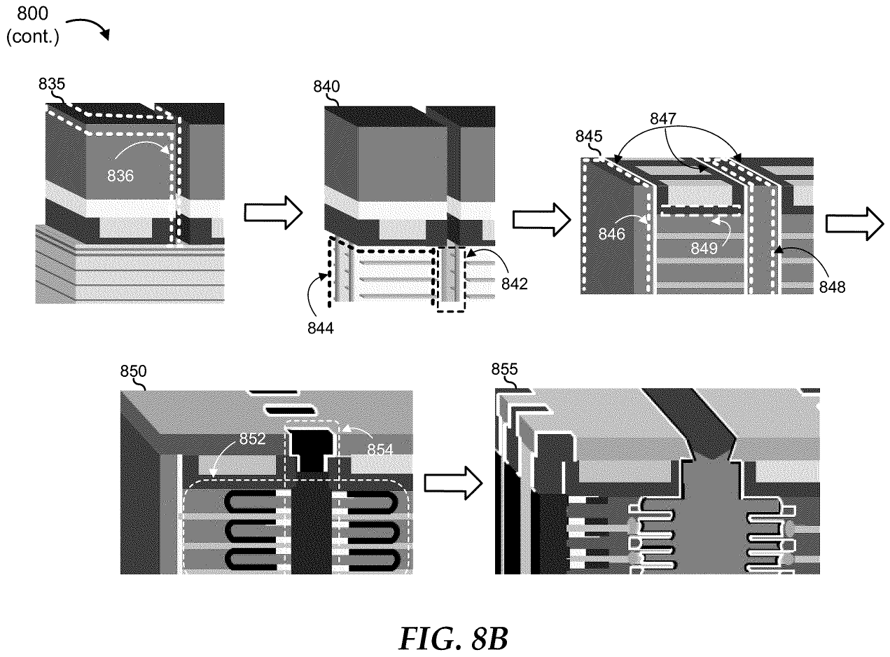

To prevent the BLMC 260 from being affected by the electric field from the nearby components, the BLMC 260 is isolated from the adjacent components, including parts of the LBL 220 and the capacitor array. This isolation may be achieved by a dielectric layer used as a spacer surrounding the BLMC 260. The dielectric may be a suitable insulating material, an oxide, or a nitride such as silicon oxide or silicon nitride. There are two options or schemes for isolation. The first option is illustrated in FIGS. 7A and 7B. The second option is illustrated in FIGS. 8A and 8B.

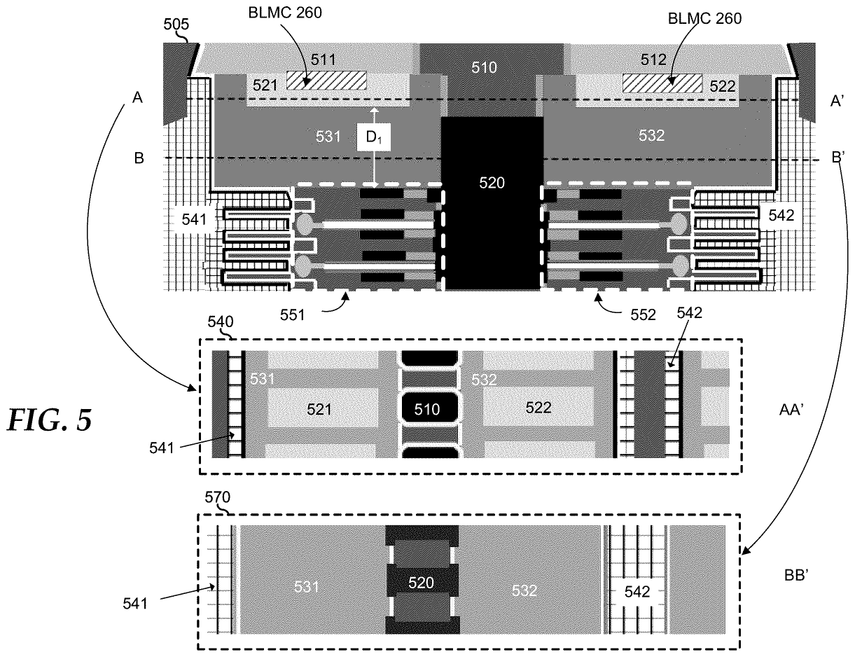

FIG. 5 is a diagram illustrating a structure 505 having a BL multiplexing circuit with an isolation structure using the first option according to an embodiment. The structure 505 has two cross-section views 540 and 570 corresponding to the two lines AA′ and BB', respectively. The lines AA′ and BB′ cross layers of the structure 505 at different distances from the top. Therefore, not all components are visible in the views.

The structure 505 includes a LBL having layers 510 and 520. There are two sets of layers on opposite sides of the LBL. The first set on the right includes layers 511, 521, 531, 541, and 551. The second set on the left includes layers 512, 522, 532, 542, and 552. The two sets symmetrical around the LBL and have the same structure and function.

The layer 510 of the LBL provides contacts and support for the 3D structure of the memory circuit. It is made of metal such as tungsten. The layer 520 provides interface and contacts for WLs and capacitor array and other transistor circuits. It may include metal or polysilicon for LBL.

The layer 511 may be a spacer layer to act as an insulator or support for the other layers underneath. It may include undoped polysilicon. The layer 521 is a silicon layer. It includes the BLMC 260 and other circuits. The layer 531 is the isolation or protection layer that protects the BLMC 260. The length from the layer 521 to the bottom line of the layer 531 is D₁. This length indicates the extent of the isolation or protection. The layer 541 may be a pathway for polysilicon plugs for connecting to memory cell or capacitor arrays. It may include conductive lines to connect to capacitors and the LBL. The area 551 may be a capacitor array that forms the memory cell array. It may include switching transistors and capacitors formed from transistors. The second set mirrors the first set. The layers 512, 522, 532, 542, and 552 are similar to the layers 511, 521, 531, 541, and 551, respectively, and therefore need no further description.

The view 540 corresponds to the line AA′ viewed from the top. The various layers 510, 521, 531, 541 are mapped as shown. The isolation or protection layer 531 surrounds the layer 521 which contains the BLMC 260.

The view 570 corresponds to the line BB′ viewed from the top. The various layers 520, 531, and 541 are mapped as shown. Since the line BB′ is below the layer 521, the layer 521 is not visible in this view. The isolation or protection layer 531 surrounds the layer 521 which contains the BLMC 260.

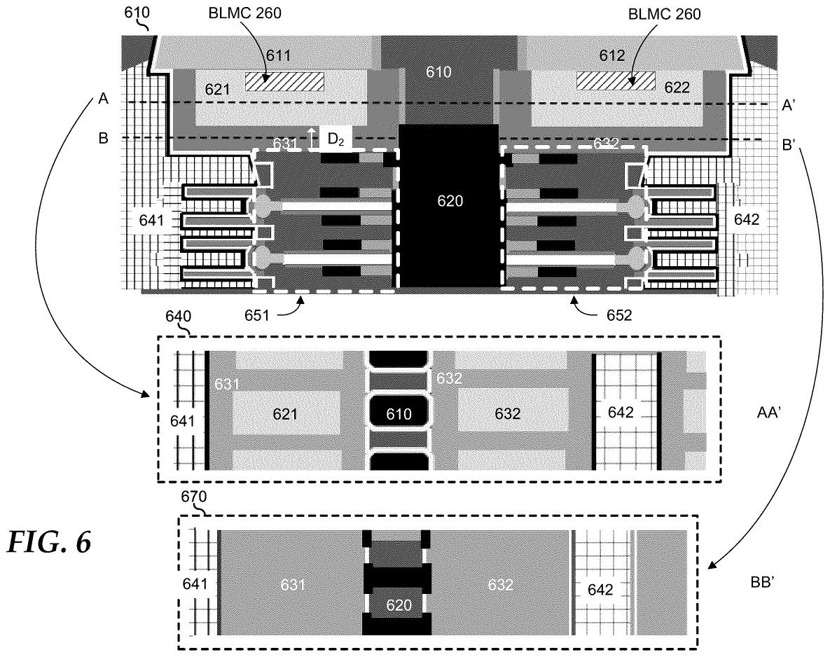

FIG. 6 is a diagram illustrating a structure 610 having a BL multiplexing circuit with an isolation structure using the second option according to an embodiment. The structure 610 has two cross-section views 640 and 670 corresponding to the two lines AA′ and BB', respectively. The lines AA′ and BB′ cross layers of the structure 610 at different distances from the top. Therefore, not all components are visible in the views.

The structure 610 includes a LBL having a layer 610 and 620. There are two sets of layers on opposite sides of the LBL. The first set on the right includes layer 611, 621, 631, 641, and 651. The second set on the left includes layer 612, 622, 632, 642, and 652. The two sets symmetrical around the LBL and have the same structure and function.

The layer 610 of the LBL provides contacts and support for the 3D structure of the memory circuit. It is made of metal such as tungsten. The layer 620 provides interface and contacts for WLs and capacitor array and other transistor circuits. It may include metal or polysilicon for LBL.

The layer 611 may be a spacer layer to act as an insulator or support for the other layers underneath. It may include undoped polysilicon. The layer 621 is a silicon layer. It includes the BLMC 260 and other circuits. The layer 631 is the isolation or protection layer that protects the BLMC 260. The length from the layer 621 to the bottom line of the layer 631 is D₁. This length indicates the extent of the isolation or protection. The layer 641 may be a pathway for polysilicon plugs for connecting to memory cell or capacitor arrays. It may include conductive lines to connect to capacitors and the LBL. The area 651 may be a capacitor array that forms the memory cell array. It may include switching transistors and capacitors formed from transistors. The second set mirrors the first set. The layers 612, 622, 632, 642, and 652 are similar to the layers 611, 621, 631, 641, and 651, respectively, and therefore need no further description.

The view 640 corresponds to the line AA′ viewed from the top. The various layers 610, 621, 631, 641 are mapped as shown. The isolation or protection layer 631 surrounds the layer 621 which contains the BLMC 260.

The view 670 corresponds to the line BB′ viewed from the top. The various layers 620, 631, and 641 are mapped as shown. Since the line BB′ is below the layer 621, the layer 621 is not visible in this view. The isolation or protection layer 631 surrounds the layer 621 which contains the BLMC 260.

FIG. 7A is a diagram illustrating a first part of a fabrication process 700 for the first isolation option according to an embodiment. The first part includes five structures 710, 715, 720, 725, and 730.

The process 700 starts with a cell/capacitor deep trench isolation (CDTI) process to create patterns or trenches on a 3D structure. The pattern includes lines or channels for silicon (Si) and silicon-germanium (Si—Ge) for forming transistors and capacitors. In some embodiments, silicon-germanium and silicon are grown in alternating layers. Silicon-germanium layers may be used as sacrificial layers that can be removed in later steps. When it is removed, the voids help for precise fabrication. In some embodiments, Si—Ge may be used to form capacitor electrodes. The process 700 then fills the etched patterns with dielectric such as silicon nitride (SiN) 711 and oxide 712 such as silicon oxide to form the structure 710. Then, the process 700 etches the CDTI pattern to the second tier silicon 716 and fills with spacer 717 to form the structure 715. Then, an isolation (ISO) process etches the structure. The silicon-germanium is removed or exhumed and a silicon thinning 723 is performed. The silicon-germanium may be removed in its entirety as a single monolithic mass. On top of a silicon nitride layer 721 is a silicon oxide layer 722. The result is the structure 720.

Next, the process 700 fills the lateral silicon-silicon spacing with an oxide dielectric 726 and cleans or trims to remove any residues to form the structure 725. Then, the process fills sacrificial amorphous carbon 732 in the ISO to the second-tier silicon 732 to expose the inter-tier lateral oxide. The result is the structure 730.

FIG. 7B is a diagram illustrating a second part of the fabrication process 700 for the first isolation option according to an embodiment. The second part includes five structures 735, 740, 745, 750, and 755.

The process 700 continues from the structure 730 to perform oxide lateral recess 737. The result is the structure 735. Next, the process thins the silicon 742 to form the structure 740. Then, the process 700 exhumes or removes the sacrificial amorphous carbon, deposits spacer to fill laterally and trims at 747 to form the structure 745.

Then, the process 700 continues with filling WLs and transistor array 752 and filling LBL 754 to form the structure 750. Next, the process 700 completes capacitor array 757 next to LBL 759, cleans, and finalizes to form the structure 755. The process 700 is then terminated.

FIG. 8A is a diagram illustrating a first part of a fabrication process 800 for the second isolation option according to an embodiment. The first part includes five structures 810, 815, 820, 825, and 830.

The process 800 starts with a CDTI process to create patterns or trenches on a 3D structure. The process 800 then fills the etched patterns with dielectric such as silicon nitride (SiN) 811 to form the structure 810. Then, the process 800 etches the CDTI pattern to the second-tier silicon 816 and fills with spacer 817 to form the structure 815. Then, the process 800 deposits a silicon nitride layer 821 and a silicon oxide layer 822. Then, an isolation (ISO) process etches the structure at 824 to land on the first silicon-germanium tier at 823. The result is the structure 820.

Then, the process 800 exhumes the first silicon-germanium tier 826 and thinning silicon 827 to form the structure 825. Next, the process 800 deposits spacer 831 to fill laterally without pinch-off. The result is the structure 830,

FIG. 8B is a diagram illustrating a second part of the fabrication process 800 for the second isolation option according to an embodiment. The second part includes five structures 835, 840, 845, 850, and 855.

The process 800 continues from the structure 830 to etch the spacer anisotropically 836 to form the structure 835. Next, the process 800 performs full ISO etch at 842. Then, the process 800 exhumes silicon-germanium and thins silicon layers at 844. The result is the structure 840.

Next, the process 800 fills laterally silicon-silicon spacings with an oxide such as silicon oxide at 846 and deposits silicon nitride liners at 847. Then, the process fills ISO at 848 with an oxide. The result is the structure 840.

Then, the process 800 continues with filling WLs and transistor array 852 and filling LBL 854 to form the structure 850. Next, the process 800 completes capacitor array 857 next to LBL 859, cleans, and finalizes to form the structure 855. The process 800 is then terminated.

The BLMC 260 helps increase the number of LBLs per GBL which provides higher density for 3D memory circuits. The implementation of the BLMC 260 may increase the saturation drain current (IDSAT). The IDSAT is proportional to the channel width of the transistor in the BLMC 260 as follows:

$$IDSAT = k * ( W / L ) * {( {V}_{gs} - {V}_{th} )}^{2} \qquad ( 1 )$$

where * is the multiplication operator, k is the process coefficient which is proportional to charge carrier mobility and gate oxide capacitance, W is the channel width, L is the channel length, V_{gs} is the gate-to-source voltage and Vₜₕ is the threshold voltage.

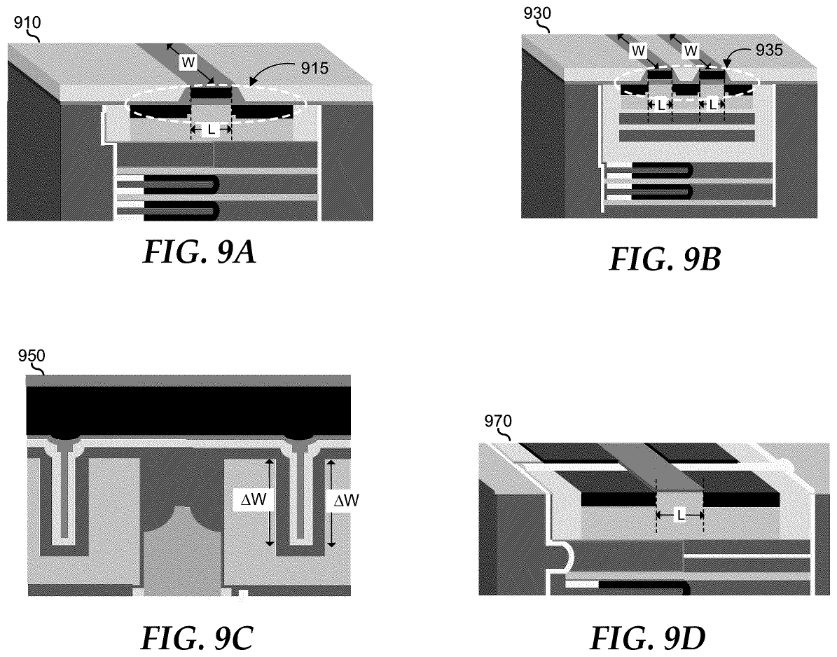

For a process implementation, k, V_{gs} and Vₜₕ are fixed parameters. W and L are the two geometrical parameters that may be changed to increase the drive current. To increase IDSAT, W can be increased or L can be reduced. But reducing L has a limit due to the short-channel effects including effects on the drive current. W is a parameter that may be changed to increase the drive current according to the arrangement of the surface of the transistor. FIGS. 9A through 9D illustrate the effective channel width for various configurations.

FIG. 9A is a diagram illustrating a structure 910 having a BL multiplexing circuit with a single gate according to an embodiment.

The structure 910 represents a transistor 915 having a single-finger configuration. The IDSAT current is proportional to the channel width. Suppose for comparison purpose, the IDSAT current has a proportionality variable as a function of W as α=1.33. The value of 1.33 is an arbitrarily chosen value for comparison purposes. The effective width is W_{eff}:

$${W}_{eff} = W \qquad ( 2 )$$

FIG. 9B is a diagram illustrating a structure 930 having a BL multiplexing circuit with a two-finger configuration according to an embodiment.

The structure 930 represents a transistor 935 having a double-finger configuration. The IDSAT current is proportional to the channel width. Since there are two widths, the proportionality variable is increased by 2: α=2.66. The effective width is:

$${W}_{eff} = 2 W \qquad ( 3 )$$

FIG. 9C is a diagram illustrating a structure 950 with a recessed channel width configuration according to an embodiment. The structure 950 shows the cross section of the width of the transistor.

In the recessed channel width configuration, the surface of the transistor is folded at a fold length of DW as shown. Accordingly, for a single-finger configuration having a geometrical width of W, with a recessed channel width, the effective width is:

$${W}_{eff} = W + 2 Δ W \qquad ( 4 )$$

The effective channel width, therefore, is increased by twice the fold length ΔW. Suppose DW is approximately close to W, say 0.62W, then for a single-finger configuration with recessed channel width, the current proportionality factor is α=3.

A multi-finger configuration with N fingers has N such folded surfaces. Accordingly, the total effective channel width is

$${W}_{eff} = N * ( W + 2 Δ W ) \qquad ( 5 )$$

For N=2, the current proportionality factor is α=6.

FIG. 9D is a diagram illustrating a structure 970 of a single gate BL multiplexing circuit with recessed channel width configuration according to an embodiment. The structure 970 shows the view without the gate layer.

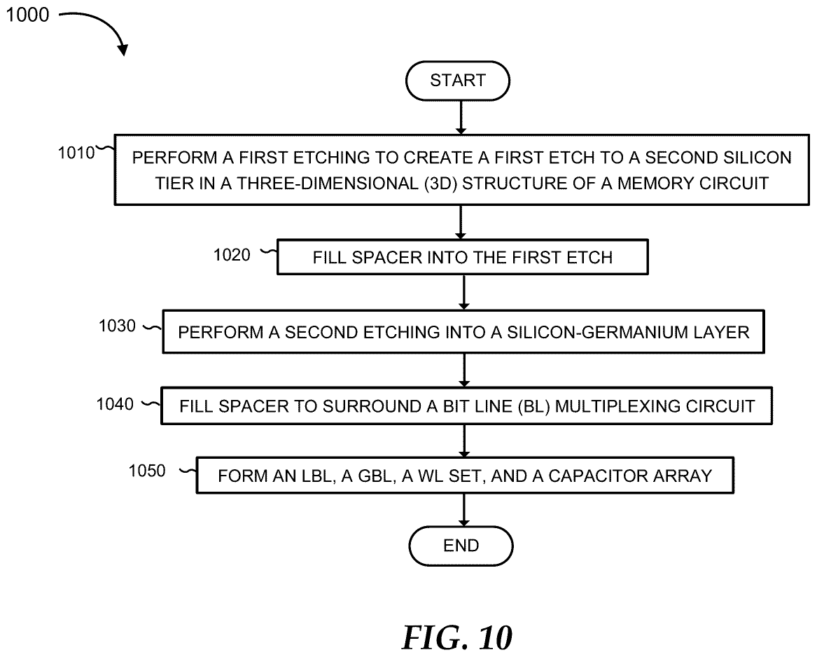

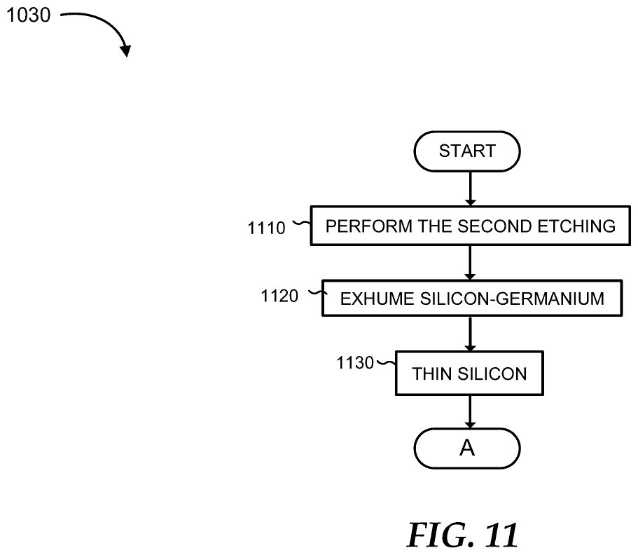

FIG. 10 is a diagram illustrating a process 1000 of forming an isolation layer to protect a BLMC according to an embodiment. The process 1000 and subsequent processes shown in FIGS. 11-14 follow the sequence of structures shown in FIGS. 7A, 7B, 8A, and 8B. In the following, references to elements or objects in these structures will be made to help illustrate the processes.

The process 1000 performs a first etching to create a first etch to a second silicon tier in a three-dimensional (3D) structure of a memory circuit (Process 1010). The process 1010 corresponds to the structures 710 in FIGS. 7A and 810 in FIG. 8A. In some embodiments, the first etching is a deep trench isolation (DTI) etching. The second silicon tier refers to the second pattern line of silicon on the 3D structure. Next, the process 1000 fills spacer into the first etch (Process 1020). The process 1020 corresponds to the elements 717 in FIGS. 7A and 817 in FIG. 8A. The spacer may be a dielectric such as silicon oxide or silicon nitride.

Then, the process 1000 performs a second etching into a silicon-germanium layer (Process 1030). The process 1030 corresponds to the structures 720 in FIGS. 7A and 820 in FIG. 8A. In some embodiments, the second etching may be an isolation (ISO) etching that creates deep and long trenches. The spacer may include an oxide or a nitride such as silicon oxide or silicon nitride. Next, the process 1000 fills spacer to surround a bit line multiplexing circuit (BLMC) (Process 1040). The process 1040 corresponds to element 748 in FIG. 7B and element 849 in FIG. 8B. Then, the process 1000 forms an LBL, a GBL, a set of WLs, and a capacitor array (Process 1050). The process 1050 corresponds to the structures 750 and 755 in FIGS. 7B and 850 and 855 in FIG. 8B. The process 1000 is then terminated.

FIG. 11 is a flow chart illustrating a first part of the process 1030 shown in FIG. 10 of performing the second etching based on the first option according to an embodiment.

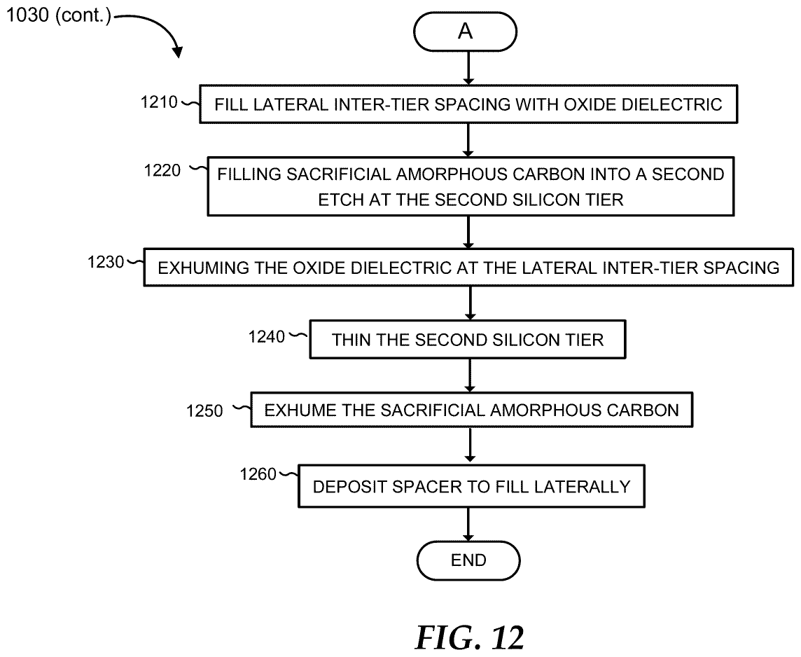

The process 1030 performs the second etching (Process 1110). The etching may be performed on the entire structure across the width (or length) of the structure limited by the etching parameters. For example, when the parameter is the width of the structure, the etching may etch the entire width (or length) to separate the structure into two structures. The process 1110 corresponds to the element 724 in the structure 720 in FIG. 7A. The element 724 shows a gap between the two sub-structures separated by the etching. Next, the process 1030 exhumes the silicon-germanium layer (Process 1120), The process 1110 corresponds to the structure 720 in FIG. 7A. Then, the process 1030 thins the silicon (Process 1120). The thinning may be applied such that the thinning operates on a part, not the entirety, of the silicon. The process 1120 corresponds to the element 723 in FIG. 7A. Next, the process 1030 proceeds to continuation node A to the second part shown in FIG. 12.

FIG. 12 is a flow chart illustrating a second part of the process 1030 shown in FIG. 10 of performing the second etching based on the first option according to an embodiment.

The process 1030 fills a lateral inter-tier spacing with oxide dielectric (Process 1210). The process 1210 corresponds to element 726 in the structure 725 in FIG. 7A. Next, the process 1030 fills sacrificial amorphous carbon into a second etch at the second silicon tier (Process 1220). The process 1220 corresponds to element 731 in the structure 730 in FIG. 7A. Next, the process 1030 exhumes the oxide dielectric at the lateral inter-tier spacing (Process 1230). The process 1230 corresponds to element 737 of the structure 735 in FIG. 7B.

Then, the process 1030 thins the second silicon tier (Process 1240). For example, the entire second silicon tier may be thinned. The process 1240 corresponds to the element 742 of the structure 740 in FIG. 7B. Next, the process 1030 exhumes the sacrificial amorphous carbon (Process 1250). The entire sacrificial amorphous carbon may be exhumed or removed. The process 1250 corresponds to the structure 745 in FIG. 7B. Then, the process 1030 deposits spacer to fill laterally (Process 1260). The process 1260 corresponds to the element 747 of the structure 745 in FIG. 7B. The process 1030 is then terminated.

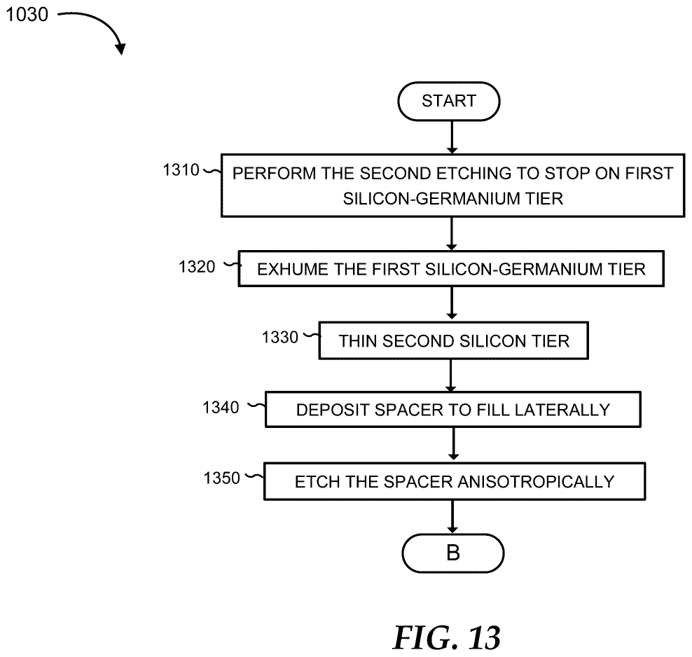

FIG. 13 is a flow chart illustrating a first part of the process 1030 shown in FIG. 10 of performing the second etching based on the second option according to an embodiment.

The process 1030 performs the second etching to stop on first silicon-germanium tier (Process 1310). The process 1310 corresponds to elements 823 and 824 of the structure 820 in FIG. 8A. Next, the process 1030 exhumes the first silicon-germanium tier (Process 1320). The process 1320 corresponds to the element 826 of the structure 825 in FIG. 8A. Then, the process 1030 thins second silicon tier (Process 1330). The process 1330 corresponds to the element 827 of the structure 825 in FIG. 8A.

Next, the process 1030 deposits spacer to fill laterally (Process 1340). The process 1340 corresponds to the element 831 of the structure 830 in FIG. 8A. Then, the process 1030 etches the spacer anisotropically (Process 1350). The process 1350 corresponds to the element 836 of the structure 835 in FIG. 8B. The process 1030 then continues to continuation node B to the second part.

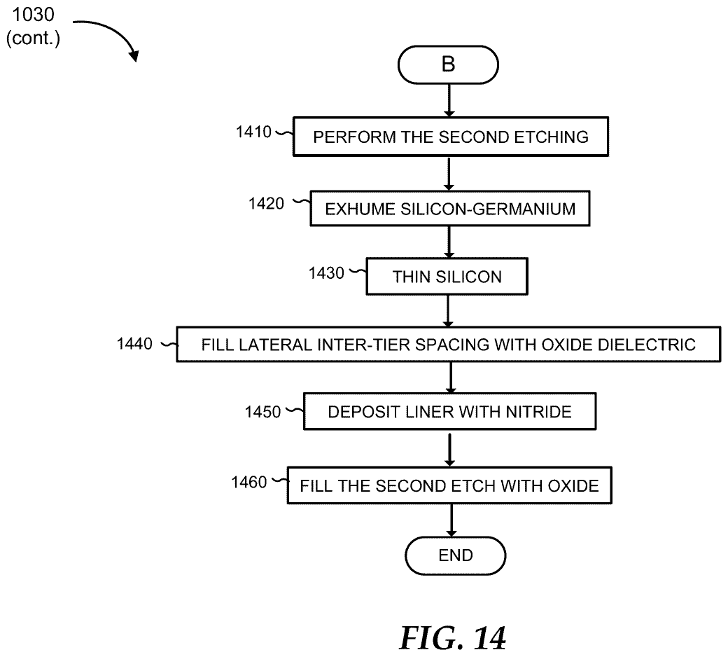

FIG. 14 is a flow chart illustrating a second part of the process 1030 shown in FIG. 10 of performing the second etching based on the second option according to an embodiment.

The process 1030 performs the second etching (Process 1410). The second etching may be performed on the structure from the first silicon-germanium tier. The process 1410 corresponds to the element 842 of the structure 840 in FIG. 8B. Next, the process 1030 exhumes the silicon-germanium layer to expose the silicon (Process 1420). The process 1420 corresponds to the element 844 of the structure 840 in FIG. 8B. Then, the process 1030 thins silicon(Process 1430). The thinning may be applied to a part of the silicon to an extent that allows for filling in the oxide dielectric. The process 1430 corresponds to the element 844 of the structure 840 in FIG. 8B.

Next, the process 1030 fills the lateral inter-tier spacing with oxide dielectric (Process 1440). The process 1440 corresponds to the element 846 of the structure 845 in FIG. 8B. Then, the process 1030 deposits liner with nitride (Process 1450). The process 1450 corresponds to the element 847 of the structure 845 in FIG. 8B. Next, the process 1030 fills the second etch with oxide (Process 1460). The process 1460 corresponds to the element 848 of the structure 845 in FIG. 8B. The process 1030 is then terminated.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a keeper configured to maintain a local bit line (LBL) at a voltage level during a pre-charge period; and
a selector configured to connect the LBL to a global bit line (GBL) based on a selection signal during a charge-sharing period,
wherein the keeper and the selector are located between the GBL and an array area of a three-dimensional (3D) memory circuit.

2. The device of claim 1, wherein at least one of the keeper or the selector is isolated from the LBL and an adjacent cell array by a dielectric layer.

3. The device of claim 1, wherein at least one of the keeper or the selector is arranged in a multi-finger configuration.

4. The device of claim 3, wherein the multi-finger configuration includes a first transistor and a second transistor having overlapped drain terminals and connected source terminals.

5. The device of claim 1, wherein at least one of the keeper or the selector includes a transistor having a channel surface folded along a width direction.

6. The device of claim 1, wherein the selection signal is generated by a control circuit.

7. The device of claim 1, wherein the keeper includes a keeper transistor having a first terminal connected to a voltage source having the voltage level and a second terminal connected to the LBL.

8. The device of claim 7, wherein the selector includes a selector transistor having a third terminal connected to the LBL and a fourth terminal connected to the GBL.

9. The device of claim 1, wherein the LBL is connected to a cell array of the memory circuit.

10. The device of claim 9, wherein at least one of the keeper or the selector is located external to the cell array.

11. A method comprising:
performing a first etching to create a first etch to a second silicon tier in a three-dimensional (3D) structure of a memory circuit;
filling spacer into the first etch;
performing a second etching into a silicon-germanium layer;
filling spacer to surround a bit line multiplexing circuit (BLMC); and
forming a local bit line (LBL), a global BL, a word line (WL) set, and a capacitor array.

12. The method of claim 11, wherein performing a second etching comprises:
performing the second etching from a first silicon-germanium tier;
exhuming silicon-germanium to expose silicon; and
thinning the silicon.

13. The method of claim 12, further comprising:
filling lateral inter-tier spacing with oxide dielectric;
filling sacrificial amorphous carbon into a second etch at the second silicon tier;
exhuming the oxide dielectric at the lateral inter-tier spacing;
thinning the second silicon tier ;
exhuming the sacrificial amorphous carbon; and
depositing spacer to fill laterally.

14. The method of claim 11, wherein performing a second etching comprises:
performing the second etching to stop on first silicon-germanium tier;
exhuming the first silicon-germanium tier;
thinning second silicon tier;
depositing spacer to fill laterally; and
etching the spacer anisotropically.

15. The method of claim 14, further comprising:
performing the second etching;
exhuming silicon-germanium to expose silicon;
thinning the silicon;
filling lateral inter-tier spacing with oxide dielectric;
depositing liner with nitride; and
filling the second etch with oxide.

16. The method of claim 11, wherein the spacer includes at least one of nitride or oxide.

17. The method of claim 11, wherein the first etching is a deep trench isolation (DTI) and the second etching is isolation (ISO).

18. The method of claim 11, wherein the BLMC has a multi-finger configuration.

19. The method of claim 11, wherein the BLMC has a channel recessed width.

20. A system comprising:
a three-dimensional (3D) memory circuit comprising:
an array area; and
a bit line multiplexing circuit (BLMC) comprising;
a keeper configured to maintain a local bit line (LBL) at a voltage level during a pre-charge period; and
a selector configured to connect the LBL to a global bit line (GBL) based on a selection signal during a charge-sharing period,
wherein the keeper and the selector are located between the GBL and the array area.
